(19) United States
(12) Patent Application Publication
(10) Pub. No.: US 2012/0112832 A1
(43) Pub. Date: May 10, 2012

(54) RADIO FREQUENCY SWITCH AND RADIO FREQUENCY MODULE

(75) Inventors: Hiroaki KAWANO, Osaka (JP); Haruhiko KOIZUMI, Osaka (JP); Kazuya WAKITA, Osaka (JP)

(73) Assignee: PANASONIC CORPORATION, Osaka (JP)

(21) Appl. No.: 13/291,180

(22) Filed: Nov. 8, 2011

(30) Foreign Application Priority Data
Nov. 9, 2010 (JP) 2010-251336

(51) Int. Cl. H03F 3/68; H03K 17/687

(52) U.S. Cl. 330/124 D; 327/427

(57) ABSTRACT

The present invention provides a radio frequency switch and a radio frequency module having excellent distortion characteristics without causing a further insertion loss and a greater chip size. The radio frequency switch includes: input-output terminals which are for inputting and outputting a radio frequency signal; a basic switching unit provided between two of the input-output terminals; and a control terminal which receives a control voltage for controlling conduction and interruption of the basic switching unit. The basic switching unit includes field effect transistors (FETs) connected in multiple stages, each of the FETs being a meandered FET having a meandered gate electrode, and among the FETs, one of the FETs has a finger length shorter than finger lengths of rest of the FETs, the one of the FETs electrically located closest to one of the input-output terminals.

### BACKGROUND OF THE INVENTION

(1) Field of the Invention

The present invention relates to switches for controlling conduction and interruption by a field effect transistor (FET) and, more particularly, to a radio frequency switch which intermittently transmits a radio frequency signal, and to a radio frequency module including the radio frequency switch.

(2) Description of the Related Art

Most of mobile communications devices, such as cellular phones, are typically configured to use one antenna for both transmission and reception so that the devices can be made smaller. In such a configuration, it is necessary to switch internal circuits connected to the antenna depending on whether the signals are transmitted or received, and a radio frequency signal switch is used for the switching. Furthermore, not only the connection with the antenna, the radio frequency switch is used when switching radio frequency signal paths in the circuits according to the communication scheme and output power. It is necessary for such a radio frequency signal switch to reduce development of interruption waves which adversely affect communications and to intermittently transmit high-power radio frequency signals. Furthermore, for reducing power consumption at the time of transmission and for improving the reception sensitivity at the time of reception, it is necessary to suppress insertion loss to a low level. Thus, the switching device used for the radio frequency signal switch has to have good distortion characteristics in transmission and reception, high power durability, and a low insertion loss.

Recently, FETs have been widely used as the switching devices. A radio frequency switch using the FET, however, has a defect that radio frequency characteristics, including distortion characteristics, further deteriorate as the input power increases. In order to overcome such a defect, there is a technique to connect FETs in series in multiple stages so as to disperse power applied to each of the FETs, and to reduce the deterioration of the radio frequency characteristics in receiving large power (See Japanese Patent No. 3736356, for example).

Hereinafter described is a radio frequency switch disclosed in a conventional technique with reference to FIG. 8. FIG. 8 exemplifies a circuit diagram of the radio frequency switch using the conventional technique. The radio frequency switch in FIG. 8 is in a circuit configuration of the single pole double throw (SPDT) having two inputs and one output.

A radio frequency switch 800 includes input-output terminals 801, 802, and 803, and basic switching units 804 and 805 provided between each of the input-output terminals 801, 802, and 803.

Each of the basic switching units 804 and 805 includes FETs connected in multiple stages. In other words, the basic switching unit 804 includes four FETs; namely FETs 810 to 813. The drains and sources of the FETs 810 to 813 are sequentially connected in series. The source of the FET 810 is connected to the input-output terminal 801. The drain of the FET 813 is connected to the input-output terminal 803. Through a corresponding one of resistive elements 831, each gate of FETs 810 to 813 is connected to a control terminal 806.

Similarly, the basic switching unit 805 has FETs 820 to 823 connected in multiple stages and in series. Through a corresponding one of resistive elements 831, each gate of FETs 820 to 823 is connected to a control terminal 807. Furthermore, the FETs 810 to 823 have the same gate width and the same finger length.

Specifically detailed here is the finger length of the FET. Meandered FETs are widely used for a radio frequency switch since they do not need a large area for the installation.

FIG. 9 exemplifies a plan view of a meandered FET. The meandered FET in FIG. 9 includes: a comb-shaped source electrode 900; a comb-shaped drain electrode 901 provided such that the teeth of the drain electrode 901 are arranged opposite the teeth of the source electrode 900, so that the teeth of the source electrode 900 and the drain electrode 901 are interlocked with each other; and a meander-shaped gate electrode 902 formed along the opening between the source electrode 900 and the drain electrode 901. In other words, each of the teeth of the source electrode 900 and the teeth of the drain electrode 901 are connected to a common portion 921. The common portion 921 is the base of the teeth of the source electrode 900 and the teeth of the drain electrode 901. The gate electrode 902 has a portion in parallel with neighboring teeth connected with an angled portion 920. Here, a finger length 930 is defined by a facing length in a longitudinal direction of the teeth of the source electrode 900 and of the drain electrode 901. It is noted that a device isolation region 910 is formed around the FET to electrically separate each of devices.

Described next is an operation of the conventional radio frequency switch in FIG. 8 whose FET is, for example, the depletion type. Suppose the case where a radio frequency signal enters at the input-output terminal 801 and goes out at the input-output terminal 803. Here, for example, an ON-voltage of approximately 3V and an OFF-voltage of approximately 0 V are applied to the control terminal 806 to make the FETs 810 to 813 conductive, and to make the FETs 820 to 823 interrupted. The radio frequency signal which enters at the input-output terminal 801 goes out at the input-output terminal 803 via the conductive FETs 810 to 813. The radio frequency signal voltage is also applied to the interrupted FETs 820 to 823. Here, a stray capacitance develops on each of the interrupted FETs 820 to 823. FIG. 10 is a circuit diagram showing stray capacitances developed on an interrupted FET used in the conventional radio frequency switch. As shown in FIG. 10, each of the interrupted FETs 820 to the 823 has (i) gate-source stray capacitances C81, C83, C85, and C87 developed respectively, (ii) gate-drain stray capacitances C82, C84, C86, and C88 developed respectively, and (iii) source-drain stray capacitances C89, C90, C91, and C92 developed respectively. In the conventional radio frequency switch, each of the FETs 820 to the 823 has the same gate width and the same finger length. Accordingly, the stray capacitances C81 to C88 have the same capacitance value, and the stray capacitances C89 to C92 have the same capacitance value. Thus, the stray capacitances C81 to C88 divide the radio frequency signal voltage into approximately eight, and to each gate of the FETs 820 to 823, the divided radio frequency signal voltage is applied. Similarly, the stray capacitances C89 to C92 divide the radio frequency signal voltage into four, and each of the divided radio frequency signal voltages is applied between the drain and the source of the corresponding one of the FETs 820 to 823 such that the divided radio frequency signal voltage is superimposed on a direct-current (DC) voltage.

Described here are harmonic distortions developed when a radio frequency signal is applied to an interrupted FET. In order to keep the FET interrupted, each of (i) the sum of the gate-drain high frequency voltage and the gate-drain DC voltage, and (ii) the sum of the gate-source high frequency voltage and the gate-source DC voltage needs to be equal to or lower than a threshold voltage of the FET. As described above, when the radio frequency signal voltage is applied to the interrupted FET, the high frequency voltages are applied between the gate and the drain and between the gate and the source. When the input power is greater, the high frequency voltage amplitude becomes wider. As a result, the gate-drain voltage and the gate-source voltage come close to the threshold voltage, which makes it difficult to maintain enough non-conductivity for the FET. Here, a part of the radio frequency signal leaks via the interrupted FET, and the waveform of the radio frequency signal is distorted. As a result, the harmonic distortions occur. Hence, the conventional technique involves connecting the FETs in multiple stages and dividing the radio frequency signal voltage in order to (i) make it difficult for the gate-source voltage and the gate-drain voltage to exceed the threshold voltage, and (ii) reduce the development of the harmonic distortions.

### SUMMARY OF THE INVENTION

Increasing the number of stages of the FETs connected in series, as shown in the conventional technique, inevitably develops a further insertion loss when the FETs are conductive. Another possible option is to increase the threshold voltage. A greater threshold voltage, however, develops a greater ON-resistance, which results in a further insertion loss when the FETs are conductive. Another possible option is to apply DC voltages, which is great enough with respect to the applied radio frequency signal voltage, between the gate and the drain and between the gate and the source. However, this option makes a gate-drain electric potential and a gate-source electric potential greater in the FET. Accordingly, the gate leakage current inevitably increases, resulting in more power consumption. Furthermore, in most cases, the maximum voltage to be applied to each terminal cannot be set to a great enough voltage due to the restrictions of the power source which supplies a voltage to the radio frequency switch, and of a circuit for the power source.

Hence, there are many trade offs which come with the reduction of harmonic distortions in the FETs. An increase in the number of the connecting stages of the FETs develops a rise in the ON-resistance, resulting in a further insertion loss. In addition, more connecting stages cause problems, such as a larger chip size and the resulting higher production cost.

The present invention is conceived in view of the above problems and has an object to provide a radio frequency switch and a radio frequency module having excellent distortion characteristics without causing problems of a further insertion loss and a greater chip size.

In order to solve the above problems, a radio frequency switch according to an aspect of the present invention includes: input-output terminals which are for inputting and outputting a radio frequency signal; a basic switching unit which is provided between a ground terminal and one of the input-output terminals or provided between two of the input-output terminals; and a control terminal which receives a control voltage for controlling conduction and interruption of the basic switching unit, wherein the basic switching unit includes field effect transistors (FETs) connected in multiple stages, each of the FETs being one of a meandered FET having a meandered gate electrode and a comb-shaped FET having a comb-shaped gate electrode, and among the FETs included in the basic switching unit, one of the FETs has a finger length shorter than finger lengths of rest of the FETs, the rest of the FETs being located electrically farther from one of (i) the one of the input-output terminals connected to an end of the basic switching unit and (ii) one of the two of the input-output terminals connected to an end of the basic switching unit than the one of the FETs is located.

Suppose basic switching units are connected in multiple stages: The distortion component, developed on an FET closer to an input-output terminal receiving the radio frequency signal, arrives at the input-output terminal with a small attenuating amount. In contrast, the distortion component developed on an FET far from the input-output terminal arrives at the input-output terminal via an interrupted FET. Thus, the harmonic distortions, developed on an FET which is located electrically closer to the input-output terminal, give a greater effect on the radio frequency signal. Hence, the finger lengths of the meandered or the comb-shaped FETs connected in multiple stages may be varied. This configuration improves the distortion characteristics of an FET closer to the input-output terminal, and provides a radio frequency switch having excellent distortion characteristics. Compared with the conventional art, the present invention can provide a smaller radio frequency switch with a lower insertion loss, as well as improve the distortion characteristics.

It is noted that the basic switching unit may be used either as a transfer switch (a switch to form a signal path for supplying a radio frequency signal inputted at one of the terminals to the other) or as a shunt switch (a switch for leading signal power leaking to an interrupted switching circuit to the ground potential) connected between the input-output terminal and the ground terminal.

In another aspect of the present invention, preferably, the basic switching unit provided between the one of the input-output terminals and the ground terminal includes: the FETs being one of meandered and comb-shaped, and connected in series; and resistive elements each of which has one end connected to a gate electrode of a corresponding one of the FETs, and another end connected to the control terminal, and among the FETs included in the basic switching unit provided between the one of the input-output terminals and the ground terminal, one of the FETs has a finger length shorter than rest of the FETs, the one of the FETs being located electrically closest to the one of the input-output terminals connected to an end of the basic switching unit, and the rest of the FETs being located electrically farther from the one of the input-output terminals than the one of the FETs is located.

The above configuration contributes to improvement in distortion characteristics, since the basic switching unit forms a switching circuit to be used as a shunt switch, and the finger length of an FET closer to the input terminal is shorter than that of an FET located electrically farther from the input terminal.

In another aspect of the present invention, preferably, the basic switching unit, provided between the one of the input-output terminals and the ground terminal, includes n transistors (n is an integer equal to or greater than 2) connected in series, and the following expression holds where FL (i) is a finger length of an i-th FET (i is an integer equal to 1 or greater and equal to n or smaller), among the FETs, from the one of the input-output terminals connected to the end of the basic switching unit: FL (1)<FL (2)≦ . . . ≦FL (n−1)≦FL (n).

Appropriate setting of a finger length, depending on effects on the distortion characteristics of each of multi-staged FETs, contributes to improvement in the distortion characteristics.

In another aspect of the present invention, preferably, the basic switching unit which is provided between the two of the input-output terminals includes: the FETs being one of meandered and comb-shaped, and connected in series; and resistive elements each of which has one end connected to a gate electrode of a corresponding one of the FETs, and another end connected to the control terminal, and when one of the two of the input-output terminals which has signal power applied is defined as an active terminal in interrupted state in the case where the basic switching unit provided between the two of the input-output terminals is interrupted, one of the FETs, among the FETs included in the basic switching unit, has a finger length shorter than rest of the FETs, the one of the FETs being located electrically closest to the active terminal in interrupted state, and the rest of the FETs being located electrically farther from the active terminal in interrupted state than the one of the FETs is located.

The above configuration contributes to improvement in the distortion characteristics, since (i) the basic switching unit forms a switching circuit to be used as a transfer switch, and, among two or more terminals, (ii) a terminal receiving signal power when the switching circuit is interrupted is defined as an “active terminal in interrupted state”, and the finger length of an FET closer to the active terminal in interrupted state is shorter than that of an FET located electrically farther from the active terminal in interrupted state.

In another aspect of the present invention, preferably, the basic switching unit, provided between the two of the input-output terminals, includes n transistors (n is an integer equal to or greater than 2) connected in series, and the following expression holds where FL (i) is a finger length of an i-th FET (i is an integer equal to 1 or greater and equal to n or smaller), among the FETs, from the active terminal in interrupted state: FL (1)<FL (2)≦ . . . ≦FL (n−1)≦FL (n).

Appropriate setting of a finger length, depending on effects on the distortion characteristics of each of multi-staged FETs, contributes to improvement in the distortion characteristics.

A radio frequency switch according to another aspect of the present invention includes any given combination of the basic switching unit provided between one of the input-output terminals among the input-output terminals and the ground terminal and the basic switching unit provided between the two of the input-output terminals wherein the radio frequency switch arbitrarily switches a flow of a radio frequency signal among the input-output terminals.

A combination of the transfer switch and the shunt switch having excellent distortion characteristics contributes to improvement in distortion characteristics in a radio frequency switch in any given topology.

In another aspect of the present invention, a radio frequency switch formed in single pole double throw includes: a first input-output terminal, a second input-output terminal, and a third input-output terminal; a first ground terminal and a second ground terminal; a first control terminal and a second control terminal; a first transfer switch provided between the first input-output terminal and the third input-output terminal; a second transfer switch provided between the second input-output terminal and the third input-output terminal; a first shunt switch provided between the first input-output terminal and the first ground terminal; and a second shunt switch provided between the second input-output terminal and the second ground terminal, wherein (i) a radio frequency signal path between the first input-output terminal and the third input-output terminal and (ii) a radio frequency signal path between the second input-output terminal and the third input-output terminal are exclusively formed with each other when (i) the first transfer switch and the second shunt switch are simultaneously either conducted or interrupted by a first control signal inputted at the first control terminal, and when (ii) the second transfer switch and the first shunt switch are simultaneously either conducted or interrupted by a second control signal inputted at the second control terminal, each of the first transfer switch and the second transfer switch is formed of the basic switching unit provided between the two of the input-output terminals, and each of the first shunt switch and the second shunt switch is formed of the basic switching unit provided between one of the input-output terminals and the ground terminal.

This configuration successfully provides a high-performance SPDT switch having excellent distortion characteristics.

In another aspect of the present invention, preferably, each of the FETs may be a multi-gate FET having at least two gate electrodes between a source electrode and a drain electrode.

The present invention can be applied to a radio frequency switch including a multi-gate FET having two or more gate electrodes between the source and the drain. This configuration contributes to improvement in distortion characteristics.

In another aspect of the present invention, a radio frequency module which amplifies a radio frequency signal includes: a first terminal which receives the radio frequency signal; a second terminal which outputs an amplified radio frequency signal; a first amplifier which amplifies the radio frequency signal; a second amplifier which amplifies the radio frequency signal; a first radio frequency switch including a first input terminal, a first output terminal, and a second output terminal, the first input terminal being connected to the first terminal, the first output terminal being connected to an input port of the first amplifier, and the second output terminal being connected to an input port of the second amplifier; and a second radio frequency switch including a second input terminal, a third input terminal, and a third output terminal, the third output terminal being connected to the second terminal, the second input terminal being connected to an output port of the first amplifier, and the third input terminal being connected to an output port of the second amplifier, wherein the first amplifier and the second amplifier exclusively operate with each other, while the first amplifier is operating, (i) the first input terminal and the first output terminal included in the first radio frequency switch become conductive and (ii) the second input terminal and the third output terminal included in the second radio frequency switch become conductive, and while the second amplifier is operating (i) the first input terminal and the second output terminal included in the first radio frequency switch become conductive and (ii) the third input terminal and the third output terminal included in the second radio frequency switch become conductive, and at least one of the first radio frequency switch and the second radio frequency switch is formed of one of the radio frequency switches.

The application of a radio frequency switch according to an implementation of the present invention to a radio frequency amplification module successfully provides a radio frequency module having excellent distortion characteristics.

The present invention provides a radio frequency switch and a radio frequency module to be made small in size, and to have excellent distortion characteristics and a low insertion loss.

### FURTHER INFORMATION ABOUT TECHNICAL BACKGROUND TO THIS APPLICATION

The disclosure of Japanese Patent Application No. 2010-251336 filed on Nov. 9, 2010 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1A shows a circuit diagram of a radio frequency switch according to Embodiment 1 of the present invention;

FIG. 1B exemplifies a plan view of the radio frequency switch according to Embodiment 1 of the present invention;

FIG. 2 shows a circuit diagram showing a stray capacitance developed on an interrupted FET used in the radio frequency switch according to Embodiment 1 of the present invention;

FIG. 3A shows a graph showing a comparison of second harmonic distortion characteristics between the radio frequency switch according to Embodiment 1 of the present invention and a conventional radio frequency switch;

FIG. 3B shows a graph showing a comparison of third harmonic distortion characteristics between the radio frequency switch according to Embodiment 1 of the present invention and the conventional radio frequency switch;

FIG. 3C shows a graph showing a comparison of insertion losses between the radio frequency switch according to Embodiment 1 of the present invention and the conventional radio frequency switch;

FIG. 4 shows a plan view of a comb-shaped FET included in a radio frequency switch according to a modification in Embodiment 1 of the present invention;

FIG. 5 shows a circuit diagram of a radio frequency switch according to Embodiment 2 of the present invention;

FIG. 6 shows a circuit diagram of a radio frequency switch according to Embodiment 3 of the present invention;

FIG. 7 shows a block diagram of a radio frequency module according to Embodiment 4 of the present invention;

FIG. 8 exemplifies a circuit diagram of a radio frequency switch using the conventional technique;

FIG. 9 exemplifies a plan view of a meandered FET; and

FIG. 10 shows a circuit diagram showing a stray capacitance developed on an interrupted FET used in the conventional radio frequency switch.

### DESCRIPTION OF THE PREFERRED EMBODIMENTS

Described hereinafter are the embodiments of the present invention with reference to the drawings.

It is noted that, in the drawings, the constitutional features sharing substantially the same configuration, operation, and effect have the same numerical references. All of the numeric values described hereinafter are exemplified to describe the present invention in detail. Therefore, the present invention shall not be limited to such values. Furthermore, the present invention is particularly useful for, but not limited to, a radio frequency switch formed on a silicon-on-insulator (SOI) semiconductor substrate, and on a compound semiconductor substrate including gallium arsenide. Moreover, the high electron mobility transistor (HEMT) and the metal semiconductor FET (MESFET) are particularly suitable as, but not limited to, the type of a field effect transistor (FET) according to an implementation of the present invention. In addition, a method for fixing an electric potential of an FET, the number of multiple stages in which FETs are connected in series, and a circuit configuration including a circuit topology of a switch are examples to describe the present invention. Therefore, the present invention shall not be limited to these.

### Embodiment 1

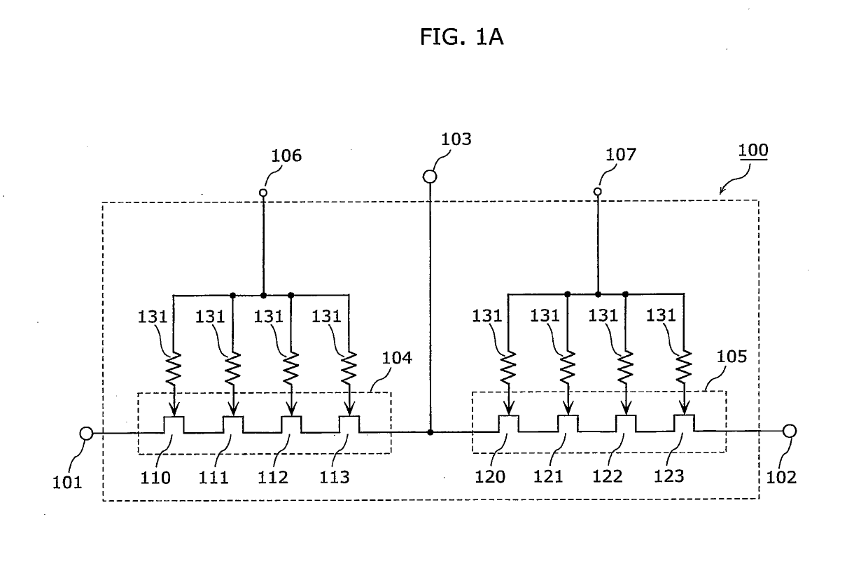

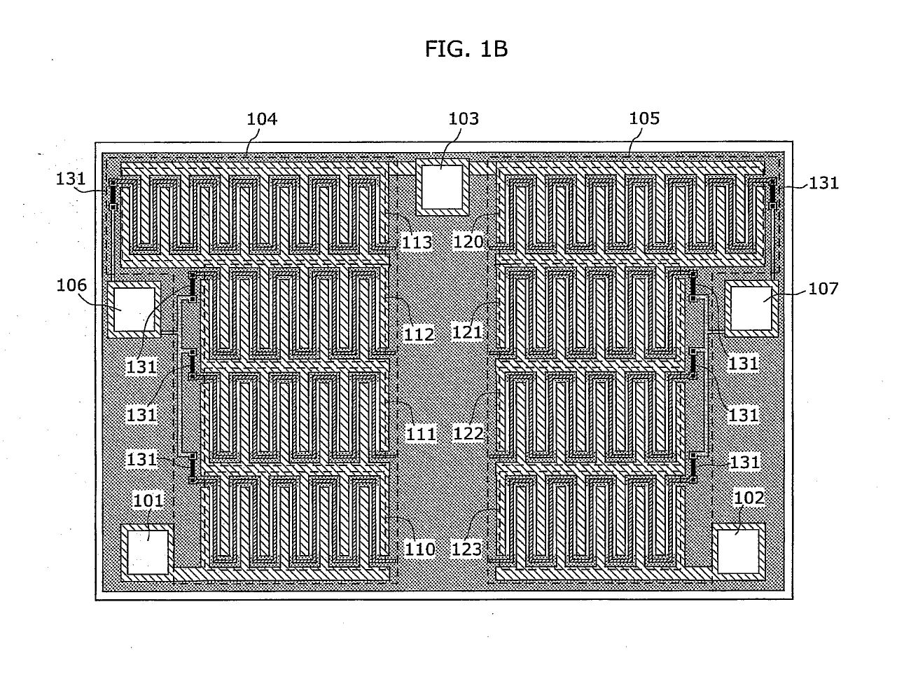

FIG. 1A shows a circuit diagram of a radio frequency switch according to Embodiment 1 of the present invention. FIG. 1B shows a plan view of the radio frequency switch according to Embodiment 1 of the present invention. A radio frequency switch 100 in FIGS. 1A and 1B includes: input-output terminals 101, 102, and 103; control terminals 106 and 107; a basic switching unit 104 having FETs 110, 111, 112, and 113; and a basic switching unit 105 having FETs 120, 121, 122, and 123. Each of resistive elements 131 has (i) one end connected to a corresponding one of the gate electrodes of the FETs, and (ii) the other end connected to one of the control terminals 106 and 107.

Embodiment 1 is characterized as follows: Among the FETs included in the radio frequency switch, the finger lengths of the FETs 113 and 120 connected to the input-output terminal 103 are shorter than the finger lengths of the rest of the FETs.

The radio frequency switch 100 shown in FIGS. 1A and 1B works as a SPDT switch circuit.

The input-output terminals 101 to 103 respectively correspond to first to third input-output terminals for inputting and outputting radio frequency signals. For example, the input-output terminal 101 connects to a transmission circuit, the input-output terminal 102 connects to a reception circuit, and the input-output terminal 103 connects to an antenna.

Connected in multiple stages and provided between the input-output terminals 101 and 103, the FETs 110 to 113 form the basic switching unit 104. Connected in multiple stages and provided between the input-output terminals 102 and 103, the FETs 120 to 123 form the basic switching unit 105. In Embodiment 1, both of the basic switching units 104 and 105 are used as transfer switches.

The control terminals 106 and 107 receive control voltages for controlling conduction and non-conduction of the basic switching units 104 and 105, respectively.

The basic switching units 104 and 105 are respectively formed of the FETs 110 to 113 connected in multiple stages and of the FETs 120 to 123 connected in multiple stages. Each of the FETs is a meandered FET having a meandered gate electrode.

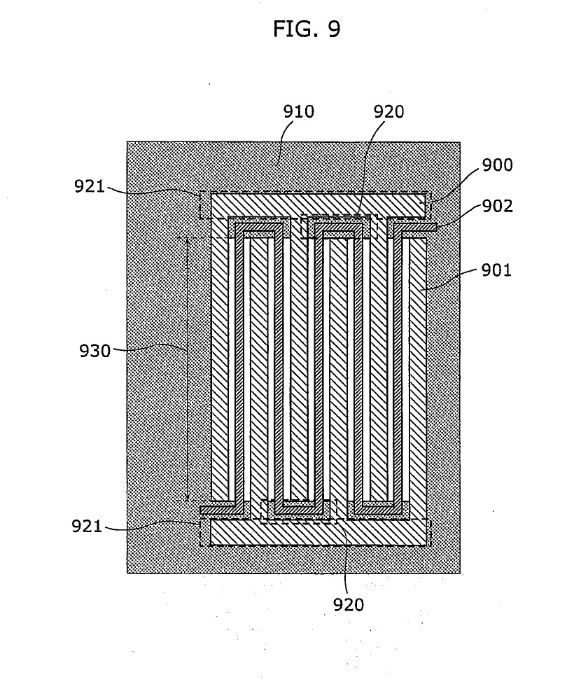

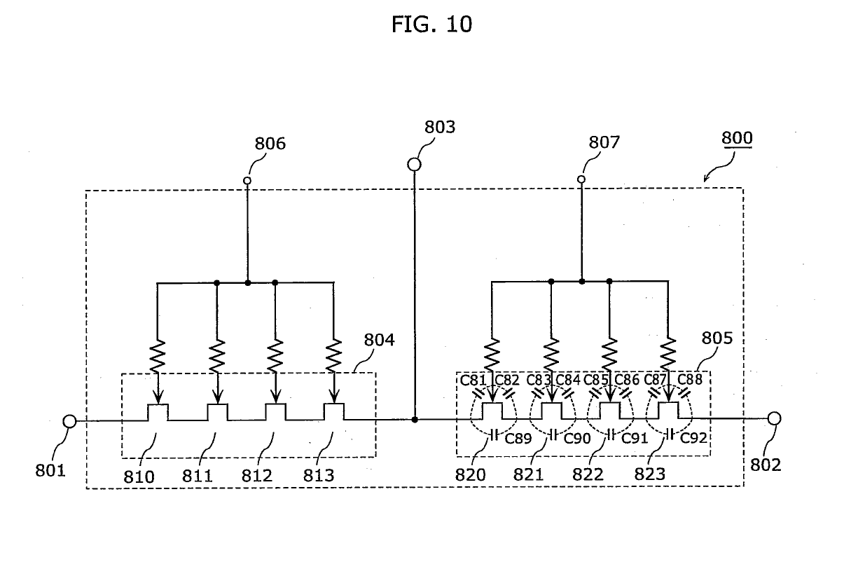

Before an operation of the radio frequency switch is described, the relationship between the finger length and the electrical characteristics of an FET shall be detailed. In view of making the installation area small, an FET used for a radio frequency switch commonly employs the meandered FET configuration, such as the one shown in FIG. 9. A meandered FET has the meandered gate electrode formed along the opening between a source electrode and a drain electrode both in comb-shaped. Neighboring teeth of the gate electrodes are connected with each other in an angled portion. Here, in the angled portion, the gate-source distance is asymmetrical to the gate-drain distance. Such an asymmetric nature is not preferable since it causes unevenness of a drain current and reduction of a breakdown voltage. Thus, in most cases, a semiconductor layer below the angled portion is used as a device isolation region. Here, the teeth are the only region to actually work as a transistor. The angled portion is not involved in driving the drain current. Even in the angled portion, however, there are gate-source and gate-drain parasitic capacitances. This partly contributes to the gate-source and gate-drain stray capacitances.

Suppose two FETs each has (i) the same actual gate width (the length of only the teeth in the meandered gate electrode) which is a gate width of a region working as a transistor and (ii) a different finger length. When the actual gate widths are the same, the FET with a shorter finger length has more angled portions. As described above, the angled portion is not involved in a transistor operation; that is, driving the drain current. However, the stray capacitance increases due to the parasitic capacitance between wires. Accordingly, an FET having the same actual gate width and a shorter finger length has more angled portions, which causes the stray capacitance to increase. In contrast, consider the ON-resistance of an FET: A shorter finger length makes wiring resistance smaller. Thus, an FET having a shorter finger length has smaller ON-resistance.

In the case where the semiconductor layer below the angled portion is not set as the device isolation region, the angled portion also works as a transistor. Compared with the teeth, however, the angled portion has a lower drain current density due to its asymmetric nature. Thus, in order to obtain the same drain current driving capacity, an FET having more angled portions needs to have a wider gate width. Accordingly, the stray capacitance becomes large as the gate width increases. It is noted that, in this configuration, a shorter finger length also makes the wiring resistance smaller.

In the above viewpoint, an FET with a shorter finger length tends to have a larger stray capacitance and a smaller ON-resistance.

Taking the above viewpoint into consideration, described hereinafter is an operation of the radio frequency switch 100 shown in FIGS. 1A and 1B, when the radio frequency switch 100 transmits a radio frequency signal from the input-output terminal 101 to the input-output terminal 103.

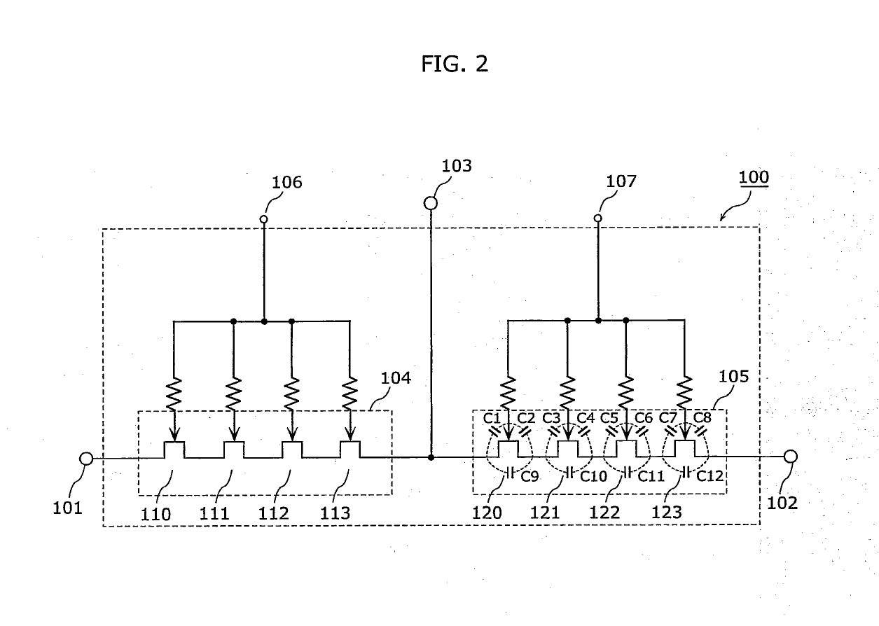

An ON-voltage and an OFF-voltage are respectively applied to the control terminal 106 and the control terminal 107. Here, the FETs 110 to 113 included in the basic switching unit 104 become conductive. The FETs 120 to 123 included in the basic switching unit 105 become interrupted. In other words, a short circuit occurs between the input-output terminal 101 and the input-output terminal 103, and an open circuit occurs between the input-output terminal 102 and the input-output terminal 103. The radio frequency signal inputted at the input-output terminal 101 is transferred to the input-output terminal 103. Here, the interrupted FETs 120 to 123 also receive the radio frequency signal voltage, and a stray capacitance develops on each of the interrupted FETs 120 to 123. FIG. 2 shows a circuit diagram showing the stray capacitance developed on each of the interrupted FETs in the radio frequency switch 100 according to Embodiment 1 of the present invention. As shown in FIG. 2, each of the interrupted FETs 120 to 123, has (i) gate-source stray capacitances C1, C3, C5, and C7 developed respectively, (ii) gate-drain stray capacitances C2, C4, C6, and C8 developed respectively, and (iii) source-drain stray capacitances C9, C10, C11, and C12 developed respectively. Thus, a radio frequency voltage is divided according to the capacitance values of the stray capacitances C1 to C8, and each of the divided radio frequency voltage is applied between the gate and the source and between the gate and the drain of each of the FETs 120 to 123. When the gate-drain electric potential or the gate-source electric potential comes closer to a threshold voltage, a radio frequency signal starts to leak via the interrupted FETs. This causes harmonic distortions.

The distortion component, developed on the FET 120 which is closest to the input-output terminal 103 that outputs the radio frequency signal, arrives at the input-output terminal 103 without attenuating. In contrast, the distortion component developed on the FET 121 arrives at the input-output terminal 103 via the interrupted FET 120. In other words, compared with the harmonic distortions developed on the FET 120, the harmonic distortions developed on the FET 121 give a smaller effect on the radio frequency signal since the latter are attenuated by the FET 120. Similarly, the harmonic distortions developed on the FET 122 are attenuated by the FETs 120 and 121. The harmonic distortions developed on the FET 123 are attenuated by the FETs 120 to 122. In other words, the harmonic distortions, developed on an FET which is electrically located closer to the input-output terminal 103, give a greater effect on the radio frequency signal.

In Embodiment 1, the finger length of the FET 120, which gives the greatest effect of the harmonic distortions on the radio frequency signal, is made shorter than the finger lengths of the rest of the FETs 121 to 123. This configuration improves the distortion characteristics. As described above, a stray capacitance improves as a finger length of a FET is shorter. Thus, the gate-source stray capacitance C2 is set smaller than the stray capacitances C4, C6, and C8. The gate-drain stray capacitance C1 is set smaller than the stray capacitances C3, C4, and C7. Hence, the voltages applied between the gate and the drain and between the gate and the source of the FET 120 are smaller than those of the FETs 121 to 123. In other words, the FET 120, which gives the greatest effect on the harmonic distortion characteristics, is easily maintained interrupted. This configuration improves the distortion characteristics. In addition, the shorter finger length also contributes to a smaller ON-resistance, successfully making the radio frequency switch 100 smaller with a low insertion loss.

It is noted that in the above description, exemplified is the case where the radio frequency signal is transferred from the input-output terminal 101 to the input-output terminal 103 in the radio frequency switch 100 shown in FIGS. 1A and 1B. Similarly considered is the case where the radio frequency signal is transferred from the input-output terminal 102 to the input-output terminal 103. In order to improve the distortion characteristics, specifically, the finger length of the FET 113 connected to the input-output terminal 103 may be shorter than the finger lengths of the rest of the FETs 110 to the 112.

Here, the finger lengths of the FETs connected in multiple stages may be varied. This configuration improves the distortion characteristics of an FET closer to the input-output terminal, and provides a radio frequency switch having excellent distortion characteristics.

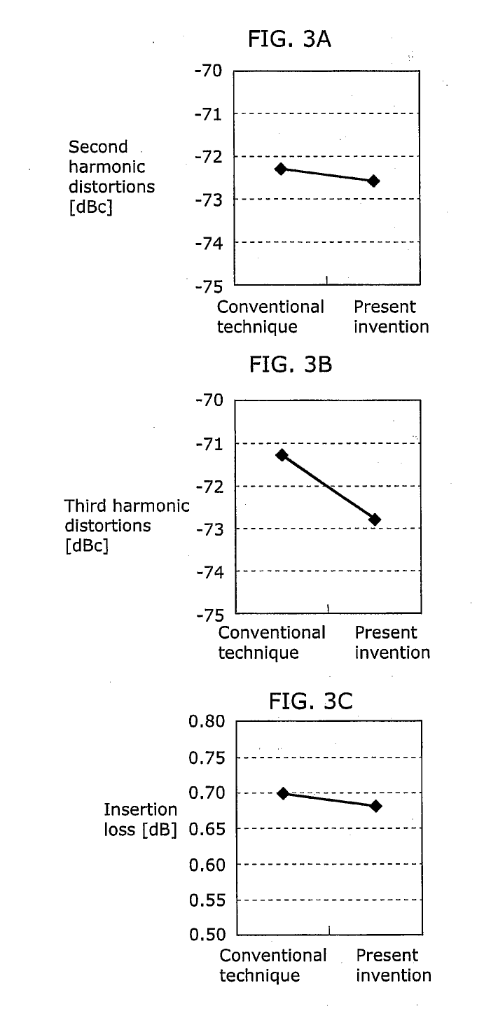

FIGS. 3A to 3C depict graphs showing comparisons between the conventional radio frequency switch and the radio frequency switch 100 according to Embodiment 1 of the present invention regarding the second harmonic distortion characteristics, the third harmonic distortion characteristics, and the insertion loss characteristics. It is noted that both of the radio frequency switches in comparison are configured to have FETs connected in four stages and in series. Each of the FETs has the actual gate length of 3000 um. In the conventional radio frequency switch, the finger length of each FET is 80 um. In the radio frequency switch 100 according to Embodiment 1, the finger lengths of the FETs 113 and 120 are 40 um, and the finger lengths of the rest of the FETs are 80 um. As shown in FIGS. 3A to 3B, the radio frequency switch 100 according to Embodiment 1 excels in the harmonic distortion characteristics and the insertion loss characteristics.

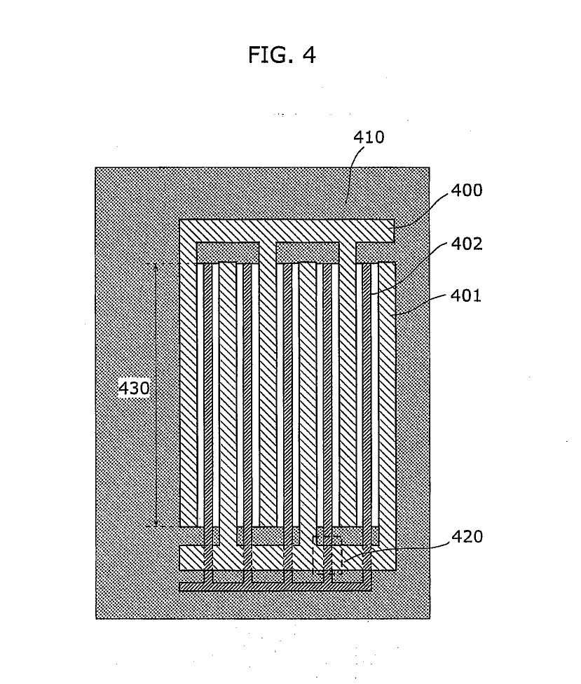

Embodiment 1 shows a meandered FET as an example. Instead, the present invention is also applicable to a comb-shaped FET. FIG. 4 shows a plan view of a comb-shaped FET included in a radio frequency switch according to a modification in Embodiment 1 of the present invention. The comb-shaped FET in FIG. 4 includes: a comb-shaped source electrode 400; a drain electrode 401 provided such that the teeth of the source electrode 400 and the teen of the drain electrode 401 are interlocked with each other; and a comb-shaped gate electrode 402 provided such that the teeth of the gate electrode 402 are arranged opposite the teeth of the source electrode 400 and of the drain electrode 401, so that the teeth of the gate electrode 402 and the teeth of the source electrode 400 and of the drain electrode 401 interlock with each other. A device isolation region 410 is formed around the FET to electrically separate each of devices. Here, a finger length 430 is defined by a facing length in a longitudinal direction of the teeth of the source electrode 400 and of the drain electrode 401. As shown in FIG. 4, the comb-shaped gate electrode 402 intersects with the drain electrode 401 on a device isolation region in an intersecting portion 420. In the intersecting portion 420, a parasitic capacitance is found between the gate and the drain. Thus, similar to a meandered FET, an FET having a shorter finger length has many of the intersecting portions 420. Accordingly, the gate-drain stray capacitance increases. Hence, similar to the case where the meandered FET is used, setting an appropriate finger length contributes to improvements in the distortion characteristics and the insertion loss characteristics. It is noted that, in the above view point, the present invention is effective in the cases where (i) the comb-shaped gate electrode 402 shares the intersecting portion with the source electrode 400, not with the drain electrode 401, and (ii) the comb-shaped gate electrode 402 shares the intersecting portion with both of the drain electrode 401 and the source electrode 400.

### Embodiment 2

Embodiment 2 mainly describes the points which differ from those in Embodiment 1. Configurations, operations, and effects similar to those in Embodiment 1 shall be omitted.

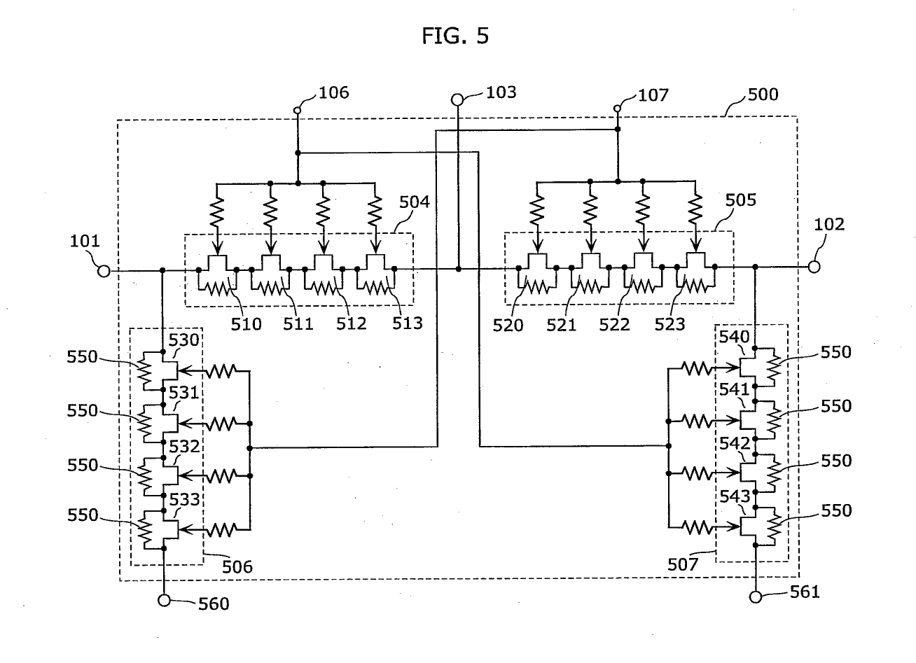

FIG. 5 shows a circuit diagram of a radio frequency switch according to Embodiment 2 of the present invention. The radio frequency switch 500 in FIG. 5 includes: the input-output terminals 101, 102, and 103; the control terminals 106 and 107; a basic switching unit 504 having FETs 510, 511, 512, and 513; a basic switching unit 505 having FETs 520, 521, 522, and 523; a basic switching unit 506 having FETs 530, 531, 532, and 533; and a basic switching unit 507 having FETs 540, 541, 542, and 543. Each of electric potential fixed resistors 550 has one end and the other end respectively connected to the source electrode and to the drain electrode of a corresponding FET in order to fix a DC potential of the corresponding FET.

Embodiment 2 is characterized in that, among the FETs included in the radio frequency switch and connected in multiple stages, an FET located closer to the input-output terminal 103 has a longer finger length. The radio frequency switch 500 in FIG. 5 is the SPDT type, and works as an SPDT switch circuit.

The input-output terminals 101 to 103 respectively correspond to first to third input-output terminals for inputting and outputting radio frequency signals. For example, the input-output terminal 101 connects to a transmission circuit, the input-output terminal 102 connects to a reception circuit, and the input-output terminal 103 connects to an antenna.

Connected in multiple stages and provided between the input-output terminals 101 and 103, the FETs 510 to 513 form the basic switching unit 504. Connected in multiple stages and provided between the input-output terminals 102 and 103, the FETs 520 to 523 form the basic switching unit 505. Connected in multiple stages and provided between the input-output terminal 101 and a ground terminal 560; namely a first ground terminal, the FETs 530 to 533 form the basic switching unit 506. Connected in multiple stages and provided between the input-output terminal 102 and a ground terminal 561; namely a second ground terminal, the FETs 540 to 543 form the basic switching unit 507.

In Embodiment 2, the basic switching units 504 and 505 are respectively used as first and second transfer switches. The basic switching units 506 and 507 are respectively used as first and second shunt switches.

Described hereinafter is an operation of the radio frequency switch 500 according to Embodiment 2, when the radio frequency signal is transferred from the input-output terminal 101 to the input-output terminal 103. An ON-voltage is applied to the control terminal 106; namely, a first control terminal. An OFF-voltage is applied to the control terminal 107; namely, a second control terminal. Here, the FETs 510 to 513 included in the basic switching unit 504 and the FETs 540 to 543 included in the basic switching unit 507 become conductive. The FETs 520 to 523 included in the basic switching unit 505 and the FETs 530 to 533 included in the basic switching unit 506 become interrupted. In other words, a short circuit occurs between the input-output terminal 101 and the input-output terminal 103, and between the input-output terminal 102 and a ground terminal 561. An open circuit occurs between the input-output terminal 102 and the input-output circuit 103, and between the input-output terminal 101 and a ground terminal 560. The radio frequency signal inputted at the input-output terminal 101 is transferred to the input-output terminal 103. It is noted that the basic switching unit 507 becomes conductive in order to prevent the radio frequency signal from leaking to the input-output terminal 102, and works as a shunt switch. As described above, among the interrupted FETs, the harmonic distortions, developed on an FET which is located electrically closer to the input-output terminal 103, give a greater effect on the radio frequency signal. Thus, the distortion characteristics are successively improved when, among the FETs 520 to 523 connected in multiple stages and the FETs 530 to 533 connected in multiple stages, an FET which is located electrically closer to the input-output terminal 103 has a shorter finger length. Specifically, in basic switching unit 505, the finger lengths may be gradually longer in the order of the FETs 520, 521, 522, and 523 (the FET 520 has the shortest finger length). In the basic switching unit 506, the finger lengths may be gradually longer in the order of the FETs 530, 531, 532, and 533 (the FET 530 has the shortest finger length).

It is noted that in the above description, exemplified is the case where the radio frequency signal is transferred from the input-output terminal 101 to the input-output terminal 103 in the radio frequency switch 500. Similarly considered is the case where the radio frequency signal is transferred from the input-output terminal 102 to the input-output terminal 103. In order to improve the distortion characteristics (i) the finger lengths may be gradually longer in the order of the FETs 513, 512, 511, and 510 (the FET 513 has the shortest finger length) in basic switching unit 504, and (ii) the finger lengths may be gradually longer in the order of the FETs 540, 541, 542, and 543 (the FET 540 has the shortest finger length) in basic switching unit 507.

Compared with the radio frequency switch 100 according to Embodiment 1, the radio frequency switch 500 according to Embodiment 2 can further reduce the harmonic distortions by optimizing each of the finger length of the FETs connected in series. Moreover, the shorter finger lengths also contribute to a smaller wiring resistance, successfully reducing the insertion loss as well.

In addition, as exemplified in Embodiment 2, the present invention may be applicable to any of a transfer switch and a shunt switch. In the case of the transfer switch, suppose an input-output terminal, to which the radio frequency signal power is applied when the interrupted state is found between the input-output terminals in the transfer switch, is defined as an active terminal in interrupted state. The distortion characteristics are successfully improved when an FET which is located electrically closer to the active terminal in interrupted state has a shorter finger length. In the case of the shunt switch, the distortion characteristics are successfully improved when an FET which is located electrically closer to the input-output terminal has a shorter finger length. In Embodiment 2, the present invention is applied to all the basic switching units; concurrently, the present invention may be applied to some of the basic switching units.

Furthermore, Embodiment 2 shows the FETs according to an aspect of the present invention as an example of applying to both of transfer switches and shunt switches; however, the circuit topology shall not be limited to this. Any given combination of the transfer switches and shunt switches according to an aspect of the present invention may provide a radio frequency switch having various circuit topologies.

Moreover, in the n pieces of FETs (n is an integer equal to or greater than 2) connected in multiple stages, the finger length does not have to be different in each of the FETs; instead, some FETs may have the same finger length. In the case of the transfer switch, the effect of the present invention is achieved when Expression 1 holds where FL (i) is the finger length of the i-th FET (“i” is an integer equal to or greater than 1 and equal to or smaller than n) from the FET closest to the active terminal in interrupted state.

FL(1)<FL(2)≦ . . . ≦FL(n−1)≦FL(n) (Expression 1)

In the case of the shunt switch, the effect of the present invention is achieved when Expression 2 holds where FL (i) is the finger length of the i-th FET (“i” is an integer equal to or greater than 1 and equal to or smaller than n) from the FET closest to the input-output terminal.

FL(1)<FL(2)≦ . . . ≦FL(n−1)≦FL(n) (Expression 2)

### Embodiment 3

Embodiment 3 mainly describes the points which differ from those in Embodiment 1. Configurations, operations, and effects similar to those in Embodiment 1 shall be omitted.

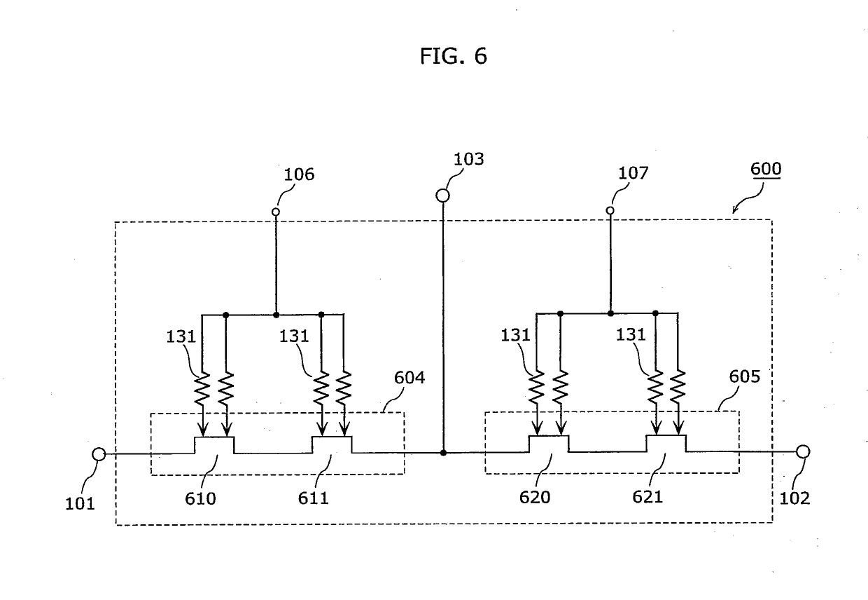

FIG. 6 shows a circuit diagram of a radio frequency switch according to Embodiment 3 of the present invention. A radio frequency switch 600 in FIG. 6 includes: the input-output terminals 101, 102, and 103; the second control terminals 106 and 107; a basic switching unit 604 having FETs 610 and 611; and a basic switching unit 605 having FETs 620 and 621.

Embodiment 3 is characterized in that the FETs included in the radio frequency switch 600 are multi-gate FETs. A multi-gate FET has at least two gate electrodes between the source electrode and the drain electrode. The radio frequency switch 600 in FIG. 6 works as an SPDT switch circuit.

The input-output terminals 101 to 103 are used for inputting and outputting radio frequency signals. For example, the input-output terminal 101 connects to a transmission circuit, the input-output terminal 102 connects to a reception circuit, and the input-output terminal 103 connects to an antenna.

Connected in multiple stages and provided between the input-output terminals 101 and 103, the FETs 610 and 611 form the basic switching unit 604. Connected in multiple stages and provided between the input-output terminals 102 and 103, the FETs 620 and 621 form the basic switching unit 604.

The basic switching units 604 and 605 are used as transfer switches.

The operation of the radio frequency switch 600 in FIG. 6 is similar to that of the radio frequency switch 100 according to Embodiment 1. In order to improve the harmonic distortion characteristics, one of the FETs 610 and 611 which is located electrically closer to the input-output terminal 103 and one of the FETs 620 and 621 which is located electrically closer to the input-output terminal 103, may have shorter finger lengths. Here, the FETs 610 and 611 are connected in multi stages, and the FETs 620 and 621 are connected in multi stages. Specifically, the finger length of the FET 611 may be shorter than that of the FET 610 in basic switching unit 604, and the finger length of the FET 620 may be shorter than that of the FET 621 in basic switching unit 605.

In general, a radio frequency switch may be formed of the multi-gate FETs shown in FIG. 6, so that the radio frequency switch can be made smaller and can achieve a lower insertion loss. The present invention is applicable to such a radio frequency switch.

It is noted that Embodiment 3 exemplifies the case where there are two gates between the source and the drain; however, the effect of the present invention shall be achieved regardless of the number of gates. Furthermore, the type of multi-gate FETs shall not be limited in particular. For example, such a multi-gate FET may have a conductive layer, between each gate, for fixing the electric potential of the semiconductor layer.

### Embodiment 4

In order to reduce power consumption, a mobile communications terminal, such as a cellular phone, controls output power of the amplifier depending on the distance to a base station. In other words, when the base station is near, the amplifier provides higher output power. When the base station is far, the amplifier provides lower output power. In theory, the efficiency of an amplifier varies depending on the output power. Thus, the maximum efficiency is not always available from all the output power.

In order to expand the output power range in which the high efficiency is available, there is a known technique to switch amplifiers depending on the output power. Embodiment 4 describes a case of applying a switching element according to an implementation of the present invention to such a switching amplifier.

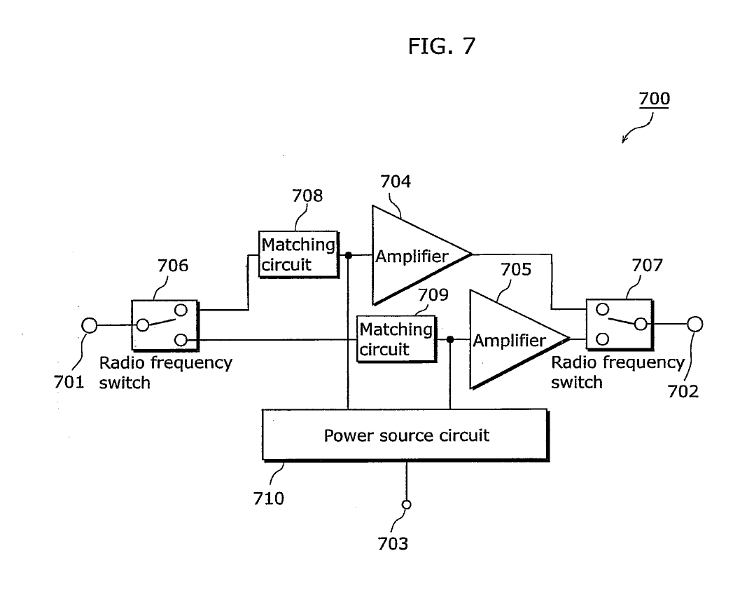

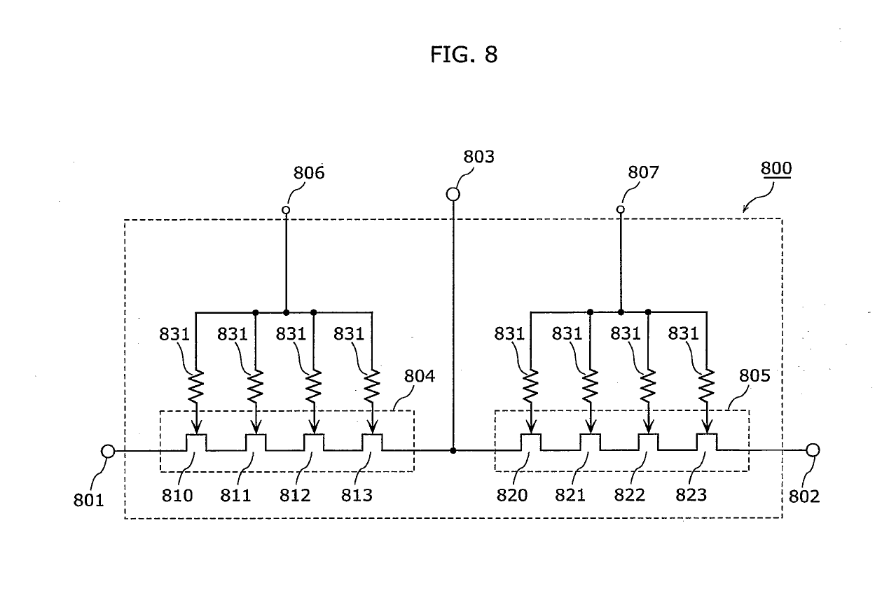

FIG. 7 shows a block diagram of a radio frequency module according to Embodiment 4 of the present invention. A radio frequency module 700 in FIG. 7 includes: an input terminal 701, an output terminal 702, a power source terminal 703, amplifiers 704 and 705, radio frequency switches 706 and 707 according to an implimentation of the present invention, matching circuits 708 and 709, and a power source circuit 710.

The radio frequency switch 706; that is a first radio frequency switch, is an SPDT circuit having one input and two outputs; namely, a first input terminal, a first output terminal, and a second output terminal. The first input terminal is connected to the input terminal 701; namely, a first terminal. The first output terminal is connected to the input port of an amplifier 704; namely a first amplifier, via the matching circuit 708. The second output terminal is connected to the input port of an amplifier 705; namely a second amplifier, via the matching circuit 709.

The radio frequency switch 707; that is a second radio frequency switch, is an SPDT circuit having two inputs and one output; namely, a second input terminal, a third input terminal, and a third output terminal. The third output terminal is connected to the output terminal 702; namely, a second terminal. The second input terminal is connected to the output port of the amplifier 704. The third input terminal is connected to the output port of the amplifier 705.

The matching circuits 708 and 709 match impedance. Each of the matching circuits 708 and 709 is loaded in order to adjust output and efficiency of the amplifiers 704 and 705.

The power source circuit 710 is provided for converting a power supply voltage to be applied to the power source terminal 703 into a bias suitable to operations of the amplifiers 704 and 705.

Each of the amplifiers 704 and 705 is designed to achieve the maximum efficiency with different output power. Described here is the case where (i) the amplifier 704 is designed to achieve the maximum efficiency in outputting low power, and (ii) the amplifier 705 is designed to achieve the maximum efficiency in outputting high power. In outputting low power, the following is observed: The amplifier 704 is in the operating state and the amplifier 705 is in the non-operating state, the first input terminal and the first output terminal in the radio frequency switch 706 are conductive, and the second input terminal and the third output terminal in the radio frequency switch 707 are conductive. In outputting high power, meanwhile, the following is observed: The amplifier 704 is in the non-operating state and the amplifier 705 is in the operating state, the first input terminal and the second output terminal in the radio frequency switch 706 are conductive, and the third input terminal and the third output terminal in the radio frequency switch 707 are conductive. Such a configuration makes it possible to achieve high efficiency in a wide output power range.

Specifically, the radio frequency module 700 causes the amplifiers 704 and 705 to exclusively operate with each other. While the amplifier 704 is operating, (i) the first input terminal and the first output terminal in the radio frequency switch 706 are conductive, and (ii) the second input terminal and the third output terminal in the radio frequency switch 707 are conductive. While the amplifier 705 is operating, (i) the first input terminal and the second output terminal in the radio frequency switch 706 are conductive, and (ii) the third input terminal and the third output terminal in the radio frequency switch 707 are conductive.

Each of the radio frequency switches 706 and 707 may be, for example, the radio frequency switch 500 according to Embodiment 2.

As described above, the present invention is useful as the radio frequency switch for switching paths in an internal circuit, as well as a radio frequency switch loaded between the antenna and the internal circuit. The application of the present invention contributes to improvement in the harmonic distortion characteristics and in efficiency of the amplifier.

It is noted that a radio frequency switch according to an implementation of the present invention is used in the configuration of the radio frequency module 700 as an example; however, the present invention shall not be limited to the above configuration. For example, (i) the number of stages of amplifiers, and (ii) the wiring and the number of the radio frequency switches and the matching circuits may be changed accordingly. Furthermore, the present invention is also applicable to a radio frequency switch for switching paths in a radio frequency module switching amplifiers for each communication mode. As a matter of course, the present invention is applicable to a radio frequency module including, a radio frequency switch for switching between an antenna and a transmission and reception circuit, an amplifier for amplifying a transmission signal, and an amplifier for amplifying a reception signal.

Although only some exemplary embodiments of a radio frequency switch and a radio frequency module of the invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

Embodiments 1 to 4 exemplified the following: In the case of the transfer switch, the FET located closest to the active terminal in interrupted state has the shortest finger length, and in the case of the shunt switch, the FET located closest to the input-output terminal has the shortest finger length. The present invention, however, shall not be limited to such FET configurations. Instead of making the finger lengths uniform among the FETs connected in multiple stages, the following relationship may be established: In two of FETs among the FETs connected in multiple stages, the FET located closer to the input-output terminal has a finger length longer than the finger length of the other FET located farther to the input-output terminal. This configuration is effective in improving the distortion characteristics of the radio frequency switch.

### INDUSTRIAL APPLICABILITY

The present invention is applicable to a radio frequency front-end module for a mobile communications device, and to a radio frequency switch used for such a module.

1. A radio frequency switch comprising:
input-output terminals which are for inputting and outputting a radio frequency signal;
a basic switching unit which is provided between a ground terminal and one of said input-output terminals or provided between two of said input-output terminals; and
a control terminal which receives a control voltage for controlling conduction and interruption of said basic switching unit,
wherein said basic switching unit includes field effect transistors (FETs) connected in multiple stages, each of said FETs being one of a meandered FET having a meandered gate electrode and a comb-shaped FET having a comb-shaped gate electrode, and
among said FETs included in said basic switching unit, one of said FETs has a finger length shorter than finger lengths of rest of said FETs, the rest of said FETs being located electrically farther from one of (i) the one of said input-output terminals connected to an end of said basic switching unit and (ii) one of the two of said input-output terminals connected to an end of said basic switching unit than the one of said FETs is located.

2. The radio frequency switch according to claim 1,
wherein said basic switching unit provided between the one of said input-output terminals and the ground terminal includes:
said FETs being one of meandered and comb-shaped, and connected in series; and
resistive elements each of which has one end connected to a gate electrode of a corresponding one of said FETs, and another end connected to said control terminal, and
among said FETs included in said basic switching unit provided between the one of said input-output terminals and the ground terminal, one of said FETs has a finger length shorter than rest of said FETs, the one of said FETs being located electrically closest to the one of said input-output terminals connected to an end of said basic switching unit, and the rest of said FETs being located electrically farther from the one of said input-output terminals than the one of said FETs is located.

3. The radio frequency switch according to claim 2,
wherein said basic switching unit, provided between the one of said input-output terminals and the ground terminal, includes n transistors (n is an integer equal to or greater than 2) connected in series, and
the following expression holds where FL (i) is a finger length of an i-th FET (i is an integer equal to 1 or greater and equal to n or smaller), among said FETs, from the one of said input-output terminals connected to the end of said basic switching unit:
FL(1)<FL(2)≦ . . . ≦FL(n−1)≦FL(n).

4. The radio frequency switch according to claim 1,
wherein said basic switching unit which is provided between the two of said input-output terminals includes:
said FETs being one of meandered and comb-shaped, and connected in series; and
resistive elements each of which has one end connected to a gate electrode of a corresponding one of said FETs, and another end connected to said control terminal, and
when one of the two of said input-output terminals which has signal power applied is defined as an active terminal in interrupted state in the case where said basic switching unit provided between the two of said input-output terminals is interrupted, one of said FETs, among said FETs included in said basic switching unit, has a finger length shorter than rest of said FETs, the one of said FETs being located electrically closest to said active terminal in interrupted state, and the rest of said FETs being located electrically farther from said active terminal in interrupted state than the one of said FETs is located.

5. The radio frequency switch according to claim 4,
wherein said basic switching unit, provided between the two of said input-output terminals, includes n transistors (n is an integer equal to or greater than 2) connected in series, and
the following expression holds where FL (i) is a finger length of an i-th FET (i is an integer equal to 1 or greater and equal to n or smaller), among said FETs, from said active terminal in interrupted state:
FL(1)<FL(2)≦ . . . ≦FL(n−1)≦FL(n).

6. A radio frequency switch comprising
any given combination of said basic switching unit provided between one of said input-output terminals among said input-output terminals and the ground terminal according to claim 2 and said basic switching unit provided between the two of said input-output terminals;
wherein said basic switching unit which is provided between the two of said input-output terminals includes:
said FETs being one of meandered and comb-shaped, and connected in series; and
resistive elements each of which has one end connected to a gate electrode of a corresponding one of said FETs, and another end connected to said control terminal, and
when one of the two of said input-output terminals which has signal power applied is defined as an active terminal in interrupted state in the case where said basic switching unit provided between the two of said input-output terminals is interrupted, one of said FETs, among said FETs included in said basic switching unit, has a finger length shorter than rest of said FETs, the one of said FETs being located electrically closest to said active terminal in interrupted state, and the rest of said FETs being located electrically farther from said active terminal in interrupted state than the one of said FETs is located; and
wherein said radio frequency switch arbitrarily switches a flow of a radio frequency signal among said input-output terminals.

7. A radio frequency switch formed in single pole double throw, said radio frequency switch comprising:
a first input-output terminal, a second input-output terminal, and a third input-output terminal;
a first ground terminal and a second ground terminal;
a first control terminal and a second control terminal;
a first transfer switch provided between said first input-output terminal and said third input-output terminal;
a second transfer switch provided between said second input-output terminal and said third input-output terminal;
a first shunt switch provided between said first input-output terminal and said first ground terminal; and
a second shunt switch provided between said second input-output terminal and said second ground terminal,
wherein (i) a radio frequency signal path between said first input-output terminal and said third input-output terminal and (ii) a radio frequency signal path between said second input-output terminal and said third input-output terminal are exclusively formed with each other when (i) said first transfer switch and said second shunt switch are simultaneously either conducted or interrupted by a first control signal inputted at said first control terminal, and when (ii) said second transfer switch and said first shunt switch are simultaneously either conducted or interrupted by a second control signal inputted at said second control terminal,
each of said first transfer switch and said second transfer switch is formed of said basic switching unit according to claim 4 provided between the two of said input-output terminals, and
each of said first shunt switch and said second shunt switch is formed of said basic switching unit provided between one of said input-output terminals and the ground terminal;
wherein said basic switching unit provided between the one of said input-output terminals and the ground terminal includes:
said FETs being one of meandered and comb-shaped, and connected in series; and
resistive elements each of which has one end connected to a gate electrode of a corresponding one of said FETs, and another end connected to said control terminal, and
among said FETs included in said basic switching unit provided between the one of said input-output terminals and the ground terminal, one of said FETs has a finger length shorter than rest of said FETs, the one of said FETs being located electrically closest to the one of said input-output terminals connected to an end of said basic switching unit, and the rest of said FETs being located electrically farther from the one of said input-output terminals than the one of said FETs is located.

8. The radio frequency switch according to claim 1,
wherein each of said FETs is a multi-gate FET having at least two gate electrodes between a source electrode and a drain electrode.

9. A radio frequency module which amplifies a radio frequency signal, said radio frequency module comprising:
a first terminal which receives the radio frequency signal;
a second terminal which outputs an amplified radio frequency signal;
a first amplifier which amplifies the radio frequency signal;
a second amplifier which amplifies the radio frequency signal;
a first radio frequency switch including a first input terminal, a first output terminal, and a second output terminal, said first input terminal being connected to said first terminal, said first output terminal being connected to an input port of said first amplifier, and said second output terminal being connected to an input port of said second amplifier; and
a second radio frequency switch including a second input terminal, a third input terminal, and a third output terminal, said third output terminal being connected to said second terminal, said second input terminal being connected to an output port of said first amplifier, and said third input terminal being connected to an output port of said second amplifier,
wherein said first amplifier and said second amplifier exclusively operate with each other,
while said first amplifier is operating, (i) said first input terminal and said first output terminal included in said first radio frequency switch become conductive and (ii) said second input terminal and said third output terminal included in said second radio frequency switch become conductive, and
while said second amplifier is operating (i) said first input terminal and said second output terminal included in said first radio frequency switch become conductive and (ii) said third input terminal and said third output terminal included in said second radio frequency switch become conductive, and
at least one of said first radio frequency switch and said second radio frequency switch is formed of said radio frequency switch according to claim 1.
